(19) United States
(12) Patent Application Publication
(10) Pub. No.: US 2017/0140922 A1
(43) Pub. Date: May 18, 2017

(54) GENERATING METHOD, IMPRINTING METHOD, IMPRINT APPARATUS, PROGRAM, AND METHOD OF MANUFACTURING ARTICLE

(71) Applicant: CANON KABUSHIKI KAISHA, Tokyo (JP)

(72) Inventors: Yuichi Iwasaki, Utsunomiya-shi (JP); Keiji Yamashita, Utsunomiya-shi (JP); Youji Kawasaki, Utsunomiya-shi (JP)

(21) Appl. No.: 15/348,693

(22) Filed: Nov. 10, 2016

(30) Foreign Application Priority Data
Nov. 13, 2015 (JP) 2015-223338

(51) Int. Cl. H01L 21/027; B05D 3/06; B05D 3/12

(52) U.S. Cl. CPC H01L 21/0273; B05D 3/12; B05D 3/066

(57) ABSTRACT

Disclosed is a method of generating a recipe for supplying an imprint material onto a substrate, the imprint material being used in imprint processing of forming a pattern on the substrate with the imprint material and a mold. The method includes obtaining first information about a volume of a pattern of the mold, and obtaining second information about a concentration of a condensable gas to be supplied to a space between the mold and the imprint material on the substrate. The condensable gas has a property of being liquefied by contact between the mold and the imprint material. The method further includes generating the recipe based on the first information and the second information.

### BACKGROUND OF THE DISCLOSURE

Field of the Disclosure

The present disclosure relates to a method of generating a recipe for supplying an imprint material to a substrate, an imprinting method, an imprint apparatus, a program, and a method of manufacturing an article.

Description of the Related Art

As demands for miniaturization of semiconductor devices and micro-electro-mechanical system (MEMS) etc. are increasing, attention is focused on microfabrication techniques as well as known photolithography techniques. A microfabrication technique is to form a pattern on a substrate by molding an imprint material (resin) on the substrate with a mold. This technique, which is called an “imprinting technique”, enables a fine structure (pattern) on the order of a few nanometers to be formed on a substrate.

Examples of imprinting techniques include a photo-curing method. An imprint apparatus using the photo-curing method molds a photo-curable resin supplied to a substrate with a mold, irradiates the resin with light to cure the resin, and separates the mold from the cured resin, thus forming a pattern on the substrate. Known imprinting techniques other than the photo-curing method include a heat-curing method in which, while a mold is in contact with a resin on a substrate, the resin is heated and cured.

A typical imprint apparatus sequentially forms patterns on a substrate in a step-and-repeat manner. The term “step-and-repeat manner” as used herein refers to a way of moving a substrate from a shot region to the next shot region in a stepwise manner each time a pattern is formed in the shot region of the substrate. Resin to be supplied to a substrate has a low viscosity. In the imprint apparatus, it is difficult to move a substrate with previously supplied resin thereon as in an exposure apparatus. U.S. Pat. No. 7,077,992 describes a dispensing manner in which resin is supplied (discharged) to a substrate each time a mold is imprinted to form a pattern in a shot region of the substrate.

Examples of techniques of supplying resin in a dispensing manner include a method disclosed in U.S. Patent Application Publication No. 2009/014917. In this method, a supply amount and supply positions of resin are determined by repeating calculation, involving Voronoi tessellation, of a set residual layer thickness based on mold information.

In imprint processing in the air, when a mold is brought into contact with resin on a substrate, the air may be trapped between the mold and the resin, causing an unfilled defect. To eliminate or reduce such an unfilled defect, the time (hereinafter, “filling time”) required to fill with the resin has to be extended while the mold is maintained in contact with the resin until the trapped air dissipates or is dissolved in the resin. A reduction in throughput caused by extending the filling time is one of the disadvantages of imprint apparatuses.

Japanese Patent No. 3700001 discloses a technique of exposing a space including a substrate or an imprint processing target region on the substrate to a condensable gas (or replacing the air or a gas in the space or the target region with the condensable gas) to reduce the filling time. According to this technique, the condensable gas trapped between a mold and resin condenses under pressure generated upon contact between the mold and the resin, thus reducing the filling time and eliminating or reducing an unfilled defect.

A report states that the use of 1,1,1,3,3-pentafluoropropane (hereinafter, “pentafluoropropane”), a kind of condensable gas, enables a reduction in force (hereinafter, “release force”) with which a mold is separated or released from cured resin (refer to Hiroshima, Journal of Vacuum Science and Technology B 27(6) (2009), 2862-2865). Reducing the release force can eliminate or reduce deposition of resin on the mold, thus reducing a defect of a pattern formed on a substrate. Furthermore, another report describes a phenomenon in which the dissolution of pentafluoropropane in resin results in a reduction in viscosity of the resin (refer to Hiroshima, Journal of Photopolymer Science and Technology Volume 23, Number 1(2010),45-50 ). The lower the viscosity of resin, the easier the resin spreads over a substrate. This leads to a reduction in filling time.

Pentafluoropropane, a kind of condensable gas, is useful to reduce the filling time, unfilled defects, and the release force (or defects caused by mold release). However, the dissolution of pentafluoropropane in resin means that the amount of resin with which a pattern (recess) of a mold is filled is reduced by the amount (hereinafter, “dissolution amount”) of pentafluoropropane dissolved in the resin. Unfortunately, a residual layer included in a pattern formed on a substrate has a thickness greater than a preset value (design value obtained without consideration of the dissolution amount). The dissolution amount of pentafluoropropane may depend on the concentration of pentafluoropropane or the kind of resin. It is necessary to optimize a supply amount and a supply position of resin on a case-by-case basis. Unfortunately, it takes a considerable amount of time.

In an atmosphere of a condensable gas, such as pentafluoropropane, the viscosity of resin lowers in accordance with the concentration of the condensable gas. The lowered-viscosity resin can readily spread over a substrate when supplied in the form of a dot (droplet) to a region on the substrate and accordingly contact another, or adjacent droplet before pressing with a mold (or contact with the mold). The contact of adjacent resin droplets may cause an unpleasant change, such as an anisotropic change, in distribution of the resin supplied to the substrate. Disadvantageously, this may affect the uniformity of residual layer thickness of a pattern formed on the substrate.

### SUMMARY OF THE DISCLOSURE

The present disclosure provides, for example, a method of generating a recipe, used to supply an imprint material to a substrate, advantageous in imprint processing in a condensable gas atmosphere.

An aspect of the present disclosure provides a method of generating a recipe for supplying an imprint material onto a substrate, the imprint material being used in imprint processing of forming a pattern on the substrate with the imprint material and a mold. The method includes obtaining first information about a volume of a pattern of the mold, and obtaining second information about a concentration of a condensable gas to be supplied to a space between the mold and the imprint material on the substrate. The condensable gas has a property of being liquefied by contact between the mold and the imprint material. The method further includes generating the recipe based on the first information and the second information.

Further features of the present disclosure will become apparent from the following description of exemplary embodiments with reference to the attached drawings.

### BRIEF DESCRIPTION OF THE DRAWINGS

FIG. 1 is a schematic diagram of an exemplary configuration of an imprint apparatus according to an embodiment of the present disclosure.

FIG. 2 is a flowchart of a method of generating a typical drop recipe.

FIG. 3 is a graph illustrating the relationship between the amount of resin supplied to a substrate and a residual layer thickness determined in each of a condensable gas atmosphere and an air atmosphere.

FIG. 4 is a flowchart of a method of generating a drop recipe according to a first embodiment.

FIG. 5 is a flowchart of a method of generating a drop recipe according to a second embodiment.

FIG. 6 is a flowchart of a method of generating a drop recipe according to a third embodiment.

FIG. 7 is a graph illustrating the relationship between the concentration of a condensable gas and the diameter of a droplet of resin on a substrate.

### DESCRIPTION OF THE EMBODIMENTS

Preferred embodiments of the present disclosure will be described with reference to the attached drawings. In the figures, the same components are designated by the same reference numerals and redundant description is avoided.

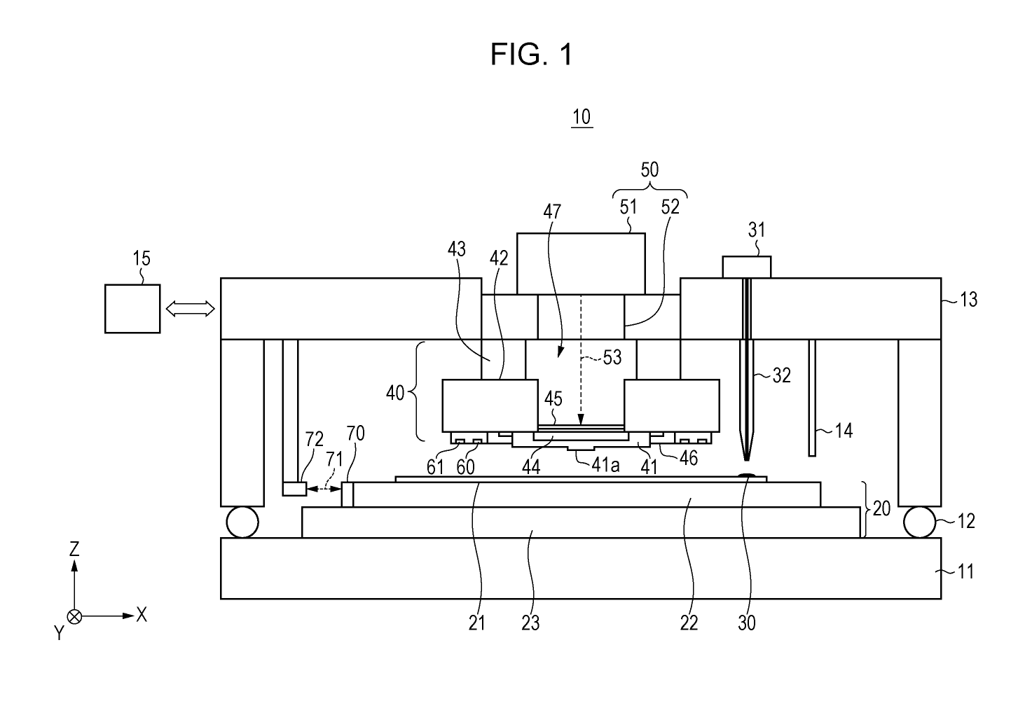

FIG. 1 is a schematic diagram of an exemplary configuration of an imprint apparatus 10 according to an embodiment of the present disclosure. The imprint apparatus 10 is used to manufacture an article, such as a device (e.g., a semiconductor device). The imprint apparatus 10 performs imprint processing for forming a pattern on a substrate with a mold. In the present embodiment, resin is used as an imprint material and a photo-curing method in which resin is cured by irradiation with ultraviolet (UV) light is used as a resin curing method. The resin curing method is not limited to the photo-curing method. A heat-curing method in which resin is cured with heat may be used.

As illustrated in FIG. 1, the imprint apparatus 10 includes a light irradiation unit (device) 50, a mold holder 40, a substrate holder 20, a dispenser 32, and a controller 15. The imprint apparatus 10 further includes a base 11, a vibration isolator 12, a frame 13, and an alignment scope 14. The base 11 supports the whole of the imprint apparatus 10 and defines a reference plane for movement of a substrate stage 23. The vibration isolator 12 has a function of isolating the frame 13 from vibrations transmitted from a floor, and supports the frame 13. The frame 13 supports components of the imprint apparatus 10 arranged above a substrate 21, for example, a light source 51, a mold 41, and the components arranged therebetween. The alignment scope 14 detects an alignment mark on the substrate 21. In the following description, the term “Z axis or direction” refers to an axis or direction identical to that of the optical axis of UV light 53 applied to resin 30 on the substrate and the terms “X axis or direction” and “Y axis or direction” refer to axes or directions orthogonal to each other in a plane perpendicular to the Z axis.

The light irradiation unit 50 irradiates the resin 30 on the substrate with the UV light 53 through the mold 41 in imprint processing, particularly, when curing the resin 30 on the substrate. The light irradiation unit 50 includes the light source 51 and an optical system 52 that adjusts the UV light 53 emitted from the light source 51 to a state suitable for imprint processing and applies the adjusted UV light to the mold 41. Since the imprint apparatus 10 uses the photo-curing method in the present embodiment, the apparatus includes the light irradiation unit 50. For example, if the imprint apparatus 10 uses the heat-curing method, the apparatus may include, instead of the light irradiation unit 50, a heat source unit for curing thermosetting resin.

The light source 51 may be a lamp, such as a halogen lamp. The light source 51 may be any light source emitting light that passes through the mold 41 and that has a wavelength at which the resin 30 is cured. The optical system 52 includes a lens, a mirror, an aperture, and a shutter for switching between irradiation with the UV light 53 and shielding from the UV light 53.

The mold 41 has a polygonal (e.g., rectangular or square) outer shape and includes a pattern portion 41a on its surface facing the substrate 21. The pattern portion 41a has a three-dimensional relief pattern (e.g., a circuit pattern) to be transferred to the substrate 21. The mold 41 is made of a material that allows the UV light 53 to pass therethrough, for example, quartz. The mold 41 has a cavity 44 in its surface to which the UV light 53 is applied. The cavity 44 is circular in plan view and has a certain depth.

The mold holder 40 includes a mold chuck 42 that holds the mold 41, a mold driving device 43 that movably holds the mold chuck 42, and a magnification correction unit 46 that corrects the shape of the mold 41 (the pattern portion 41a). The mold chuck 42 holds the mold 41 by attracting an outermost region of an irradiation area, which is to be irradiated with the UV light 53, of the mold 41 with vacuum suction force or electrostatic force. For example, to hold the mold 41 with vacuum suction force, the mold chuck 42 is connected to a vacuum pump (not illustrated) disposed outside the apparatus. Attraction pressure of the mold chuck 42 is appropriately controlled by evacuation of the vacuum pump, thus controlling attraction force (holding force) applied to the mold 41.

The mold driving device 43 moves the mold 41 in the Z direction to selectively bring the mold 41 into contact with the resin 30 on the substrate (imprinting the mold 41) or separate the mold 41 from the resin 30 on the substrate (releasing the mold 41). The mold driving device 43 includes a linear motor and an air cylinder. The mold holder 40 may include a plurality of driving systems, such as a coarse-motion driving system and a fine-motion driving system, to position the mold 41 with high accuracy. The mold driving device 43 may have a function of adjusting the position of the mold 41 not only in the Z direction but also in the X and Y directions, or in a θ direction (rotation about the Z axis) and a function of correcting the tilt of the mold 41. Although the operation of imprinting the mold 41 and the operation of releasing the mold 41 in the imprint apparatus 10 may be achieved by moving the mold 41 in the Z direction, these operations may be achieved by moving the substrate 21 in the Z direction. The operations may be performed by moving the mold 41 and the substrate 21 relative to each other.

The magnification correction unit 46 is disposed in the mold chuck 42. The magnification correction unit 46 applies external force to, or mechanically displaces side surfaces of the mold 41 to correct, or deform the shape of the mold 41 (the pattern portion 41a).

Each of the mold chuck 42 and the mold driving device 43 has a light-passing area 47 in its central (inner) part. The light-passing area 47 enables the substrate 21 to be irradiated with the UV light 53 from the light irradiation unit 50. The mold chuck 42 or the mold driving device 43 includes a light-transmissive member 45, such as a glass plate, for defining the cavity 44 surrounded by part of the light-passing area 47 and the mold 41 as a closed space. A pressure inside the cavity 44 is controlled by a pressure regulator (not illustrated) including a vacuum pump. For example, when the mold 41 is brought into contact with the resin 30 on the substrate, the pressure regulator controls a pressure inside the cavity 44 to a value higher than a pressure outside the cavity 44, thus deforming the pattern portion 41a such that the pattern portion 41a protrudes toward the substrate 21. Consequently, central part of the pattern portion 41a can be first brought into contact with the resin 30 on the substrate. This eliminates or reduces a likelihood that gas may remain between the pattern portion 41a and the resin 30, so that the pattern portion 41a can be completely filled with the resin 30.

A gas supply device 60 is disposed in the mold holder 40 or in the vicinity of the mold holder 40. The gas supply device 60 supplies a condensable gas to a space between the mold 41 (the pattern portion 41a) and the substrate 21 (the resin 30 on the substrate) in imprint processing. The condensable gas has a property of being liquefied by contact between the mold 41 and the resin 30 on the substrate. The condensable gas has a solubility not less than 0.2 mol/L into the resin 30 at 20° C. under 1 atmospheric pressure (1 atm). Examples of the condensable gas include pentafluoropropane, which has a boiling point of approximately 15° C. and a saturated vapor pressure of approximately 0.14 MPa at 23° C. Replacing the air in the space between the mold 41 and the substrate 21 with the condensable gas can eliminate or reduce an unfilled defect, which is caused by the air remaining between the mold 41 and the resin 30 on the substrate.

A gas recovering device 61 is disposed in the mold holder 40 or in the vicinity of the mold holder 40 such that the gas recovering device 61 surrounds the gas supply device 60. The gas recovering device 61 recovers the condensable gas supplied to the space between the mold 41 and the substrate 21 by the gas supply device 60.

Examples of the substrate 21 include a monocrystalline silicon substrate and a silicon-on-insulator (SOI) substrate. The pattern portion 41a of the mold 41 is used to form patterns of the resin 30 in a plurality of shot regions of the substrate 21. Typically, a pattern (a pattern portion on the substrate) is formed in each shot region of the substrate 21 by wafer processing prior to loading the substrate 21 into the imprint apparatus 10.

The substrate holder 20 movably holds the substrate 21. For example, when the mold 41 is brought into contact with the resin 30 on the substrate, the substrate holder 20 is used to align the mold 41 (the pattern portion 41a) with the substrate 21 (a pattern portion on the substrate). The substrate holder 20 includes a substrate chuck 22 that holds the substrate 21 by attraction force and the substrate stage 23 that is movable in each axial direction while mechanically holding the substrate chuck 22.

The substrate stage 23 includes a linear motor and a planar motor. The substrate stage 23 may include a plurality of driving systems, such as a coarse-motion driving system and a fine-motion driving system, for each of the X and Y directions. The substrate stage 23 may have, for example, a function of adjusting the position of the substrate 21 in the Z direction, a function of adjusting the position of the substrate 21 in the θ direction, and a function of correcting the tilt of the substrate 21.

The substrate holder 20 includes a plurality of reference mirrors 70 on its side surfaces such that the reference mirrors 70 correspond to the X, Y, Z, ωX, ωY, and ωZ directions. A plurality of laser interferometers 72 are arranged in one-to-one correspondence to the reference mirrors 70. Each laser interferometer 72 applies a laser beam 71 to the corresponding reference mirror 70 to determine the position of the substrate stage 23 (the substrate 21). FIG. 1 illustrates only one combination of the reference mirror 70 and the laser interferometer 72. The laser interferometers 72 determine the position of the substrate stage 23 in real time. The controller 15 positions the substrate stage 23 based on the position of the substrate stage 23 determined by the laser interferometers 72. Examples of a mechanism for determining the position of the substrate stage 23 include an encoder using a semiconductor laser in addition to the laser interferometer 72.

The dispenser 32 is disposed in the vicinity of the mold holder 40. The dispenser 32 includes a container 31 for holding the resin 30 in an uncured state. The dispenser 32 supplies the resin 30 to the substrate (each shot region of the substrate 21). In the present embodiment, the resin 30 is a UV-curable resin that is curable by irradiation with the UV light 53. The kind of the resin 30 is appropriately selected in accordance with various conditions, such as semiconductor device manufacturing steps.

The dispenser 32 includes a piezo-element actuated discharging mechanism for discharging a droplet of the resin 30. The amount (discharge amount) of a droplet of the resin 30 discharged from the dispenser 32 can be set in a range of 0.1 to 10 pL/droplet. Typically, the discharge amount is often set to approximately 2 pL/droplet.

A supply amount and a supply position of the resin 30 to be supplied from the dispenser 32 are controlled based on an instruction from the controller 15, specifically, a drop recipe provided by the controller 15. The term “drop recipe” as used herein refers to a recipe that is used to supply resin for imprint processing to a substrate. This recipe includes information about a supply amount of the resin 30 to be supplied to a substrate and a supply position of the resin 30 to be supplied to the substrate. The drop recipe is also called a resin coating pattern or an imprint recipe.

The controller 15 includes a central processing unit (CPU) and a memory, and controls the whole of the imprint apparatus 10. The controller 15 functions as a processor that controls the components of the imprint apparatus 10 to perform imprint processing. The controller 15 may be accommodated together with the components of the imprint apparatus 10 in a single housing or may be separated from the components of the imprint apparatus 10 such that the controller 15 is accommodated in a different housing.

The controller 15 can have a function of generating a drop recipe including information about a supply amount and a supply position of the resin 30 to be supplied to a substrate. The controller 15 may implement a function of acquiring pattern information about a pattern of the mold 41 and a function of acquiring information (second information) about the concentration of a condensable gas to be supplied to the space between the mold 41 and the resin 30 on the substrate. Furthermore, the controller 15 may implement a function of generating a drop recipe based on information (first information) about the volume of the pattern of the mold 41 and the information about the concentration of the condensable gas.

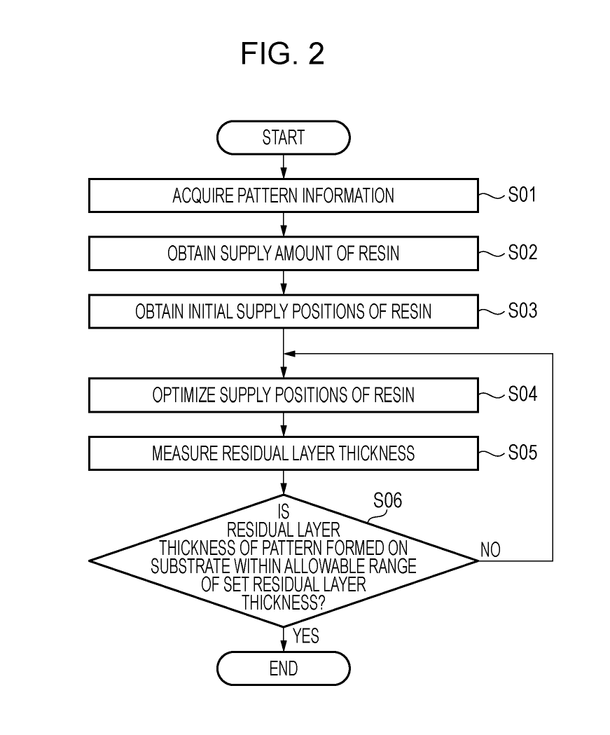

A method of generating a typical drop recipe for a case where the space between the mold 41 and the resin 30 on the substrate is in an air atmosphere will now be described with reference to FIG. 2. In S01, pattern information about a pattern of the mold 41 is acquired (obtained). The pattern information includes (fourth information) about arrangement of elements of the pattern of the mold 41, the direction of the pattern, the width of the pattern, the depth of a recess of the pattern in the pattern portion 41a, and the occupancy area of the recess.

In S02, a supply amount of the resin 30 to be supplied to the substrate is obtained based on the pattern information acquired in S01 so that a set residual layer thickness (residual layer thickness of a pattern formed on the substrate) is obtained in the case where the space between the mold 41 and the resin 30 on the substrate is in the air atmosphere. The supply amount of the resin 30 to be supplied to the substrate is obtained from the sum of the product of the area of a shot region on the substrate 21 and the set residual layer thickness and the product of the depth of the recess of the pattern in the pattern portion 41a and the occupancy area of the recess.

In S03, initial supply positions of the resin 30 to be supplied to the substrate are obtained. Specifically, the number of droplets of the resin 30 to be supplied to the substrate 21 is obtained based on the supply amount of the resin 30 obtained in S02 and the amount (discharge amount) of a droplet of the resin 30 to be discharged from the dispenser 32. Then, the initial supply positions of the resin 30 to be supplied to the substrate are obtained based on the number of droplets using Voronoi tessellation.

In S04, supply positions of the resin 30 to be supplied to the substrate are optimized based on the initial supply positions of the resin 30 obtained in S03. A speed at which the supplied resin 30 spreads over the substrate depends on the direction of the pattern of the mold 41. The initial supply positions of the resin 30 are appropriately changed based on the direction of the pattern of the mold 41 to determine the supply positions of the resin 30 on the substrate so that the set residual layer thickness is obtained.

In S05, the resin 30 is supplied to the substrate at the supply positions optimized in S04, the resin 30 is formed into a pattern on the substrate with the mold 41 (through imprint processing), and the residual layer thickness of the pattern formed on the substrate is measured.

In S06, whether the residual layer thickness of the pattern formed on the substrate is within an allowable range of the set residual layer thickness is determined based on the residual layer thickness measured in S05. If the residual layer thickness of the pattern formed on the substrate is out of the allowable range of the set residual layer thickness, the process returns to S04. Steps S04 to S06 are repeated until the residual layer thickness of the pattern formed on the substrate is within the allowable range of the set residual layer thickness. On the other hand, if the residual layer thickness of the pattern formed on the substrate is within the allowable range of the set residual layer thickness, the process is terminated. Thus, a drop recipe including the supply positions optimized in S04 is generated. In S06, whether the uniformity of the residual layer thickness in the shot region is within an allowable range may be determined in addition to the determination as to whether the residual layer thickness of the pattern formed on the substrate is within the allowable range of the set residual layer thickness.

As described above, the drop recipe for the case where the space between the mold 41 and the resin 30 on the substrate is in the air atmosphere can be generated using the method of FIG. 2. If the space between the mold 41 and the resin 30 on the substrate is in a condensable gas atmosphere, the set residual layer thickness could not be obtained upon imprint processing based on the drop recipe generated by the method of FIG. 2. The reason is that the condensable gas, supplied to the space between the mold 41 and the resin 30 on the substrate, can dissolve in the resin 30 supplied to the substrate.

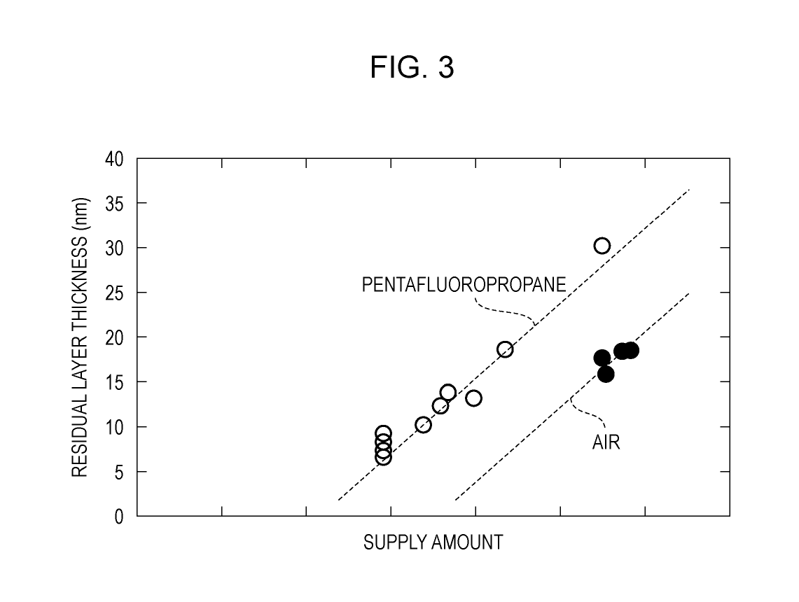

FIG. 3 is a graph illustrating the relationship between the supply amount of the resin supplied to the substrate and the residual layer thickness obtained by imprint processing in each of the condensable gas atmosphere and the air atmosphere. In FIG. 3, the axis of ordinates denotes the residual layer thickness [nm] of a pattern formed on the substrate and the axis of abscissas denotes the supply amount of the resin supplied to the substrate. In this case, the condensable gas used was pentafluoropropane and a mold and a resin used for the pentafluoropropane atmosphere were the same as those for the air atmosphere. Referring to FIG. 3, assuming that the set residual layer thickness is, for example, 15 nm, the supply amount of the resin to be supplied to the substrate in the pentafluoropropane atmosphere has to correspond to approximately two-thirds of the supply amount of the resin to be supplied to the substrate in the air atmosphere. Such a difference corresponds to the amount of pentafluoropropane dissolved in the resin on the substrate, namely, the dissolution amount of pentafluoropropane.

The dissolution amount of pentafluoropropane depends on the concentration of pentafluoropropane or the kind of resin supplied to the substrate. In the use of the method of FIG. 2, it is necessary to optimize a supply amount and supply positions of resin included in a drop recipe each time the kind of resin or the concentration of pentafluoropropane is changed. It would take too much time.

Methods of generating a drop recipe useful for imprint processing in an atmosphere of a condensable gas, such as pentafluoropropane, will now be described in the following embodiments.

### First Embodiment

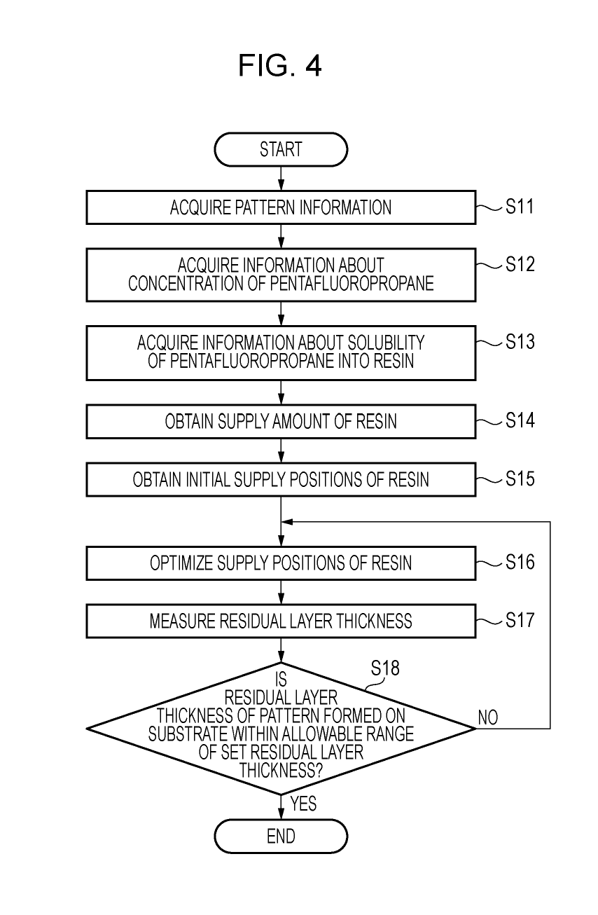

FIG. 4 is a flowchart of a method of generating a drop recipe for a case where the space between the mold 41 and the resin 30 on the substrate is in a pentafluoropropane atmosphere according to a first embodiment.

In S11, pattern information about a pattern of the mold 41 is acquired (obtained). As described above, the pattern information includes arrangement of elements of the pattern of the mold 41, the direction of the pattern, the width of the pattern, the depth of a recess of the pattern in the pattern portion 41a, and the occupancy area of the recess.

In S12, information about the concentration of pentafluoropropane in the space between the mold 41 and the resin 30 on the substrate in imprint processing is acquired (obtained). If a mixture prepared by diluting pentafluoropropane with, for example, air or helium is supplied to the space between the mold 41 and the resin 30 on the substrate, the concentration of pentafluoropropane can be obtained from the mixture ratio. In some embodiments, an optical interferometer is used to measure the index of refraction of the space between the mold 41 and the resin 30 on the substrate, and the concentration of pentafluoropropane is obtained from the measurement. In some embodiments, the concentration of pentafluoropropane is obtained from a result of measurement by, for example, a flon (chlorofluorocarbon (CFC)) detector (meter) or an infrared spectrometer.

In S13, information (fifth information) about the solubility of pentafluoropropane into the resin 30 on the substrate is acquired (obtained). For example, the solubility of pentafluoropropane into the resin 30 on the substrate can be obtained by bubbling pentafluoropropane through the resin 30 in advance (or dissolving pentafluoropropane in the resin 30 until saturation). The solubility of pentafluoropropane into the resin 30 on the substrate may be obtained by any way other than by bubbling.

In S14, a supply amount of the resin 30 to be supplied to the substrate is obtained based on the pattern information, the concentration, and the solubility acquired in S11, S12, and S13 so that a set residual layer thickness is obtained in the case where pentafluoropropane is contained in the space between the mold 41 and the resin 30 on the substrate. Specifically, a supply amount of the resin 30 to be supplied to the substrate in the case where the space between the mold 41 and the resin 30 on the substrate is in the air atmosphere is obtained. The supply amount can be obtained from the sum of the product of the area of each shot region of the substrate 21 and the set residual layer thickness and the product of the depth of the recess of the pattern in the pattern portion 41a and the occupancy area of the recess in the same manner as in S02. Then, a dissolution amount of the condensable gas to be dissolved into the resin 30 on the substrate is obtained. The dissolution amount can be obtained from the product of the concentration acquired in S12, the solubility acquired in S13, the depth of the recess of the pattern in the pattern portion 41a of the mold 41, and the occupancy area of the recess. After that, the difference between the supply amount of the resin 30 to be supplied to the substrate in the case where the space between the mold 41 and the resin 30 on the substrate is in the air atmosphere and the dissolution amount of the condensable gas to be dissolved into the resin 30 on the substrate is obtained. This difference corresponds to a supply amount of the resin 30 to be supplied to the substrate in the case where pentafluoropropane is contained in the space between the mold 41 and the resin 30 on the substrate.

The supply amount, SA1, of the resin in the pentafluoropropane atmosphere is given by the following expression (1):

SA1=SA2−x·y·h·r (1)

where SA2 denotes the supply amount of the resin in the air atmosphere, x denotes the concentration of pentafluoropropane, y denotes the solubility of pentafluoropropane, h denotes the depth of the recess of the pattern in the pattern portion 41a of the mold 41, and r denotes the occupancy area of the recess.

In S15, initial supply positions of the resin 30 to be supplied to the substrate are obtained. Specifically, the number of droplets of the resin 30 to be supplied to the substrate 21 is obtained based on the supply amount of the resin 30 obtained in S14 and the amount (discharge amount) of a droplet of the resin 30 to be discharged from the dispenser 32. Then, the initial supply positions of the resin 30 to be supplied to the substrate are obtained based on the number of droplets using Voronoi tessellation.

In S16, supply positions of the resin 30 to be supplied to the substrate are optimized based on the initial supply positions of the resin 30 obtained in S15. As described above, a speed at which the supplied resin 30 spreads over the substrate depends on the direction of the pattern of the mold 41. The initial supply positions of the resin 30 are appropriately changed based on the direction of the pattern of the mold 41 to determine the supply positions of the resin 30 on the substrate so that the set residual layer thickness is obtained.

In S17, the resin 30 is supplied to the substrate at the supply positions optimized in S16, the resin 30 is formed into a pattern on the substrate with the mold 41 (through imprint processing), and the residual layer thickness of the pattern formed on the substrate is measured.

In S18, whether the residual layer thickness of the pattern formed on the substrate is within an allowable range of the set residual layer thickness is determined based on the residual layer thickness measured in S17. If the residual layer thickness of the pattern formed on the substrate is out of the allowable range of the set residual layer thickness, the process returns to S16. Steps S16 to S18 are repeated until the residual layer thickness of the pattern formed on the substrate is within the allowable range of the set residual layer thickness. On the other hand, if the residual layer thickness of the pattern formed on the substrate is within the allowable range of the set residual layer thickness, the process is terminated. Thus, a drop recipe including the supply positions optimized in S16 is generated. In S18, whether the uniformity of the residual layer thickness in the shot region is within an allowable range may be determined in addition to the determination as to whether the residual layer thickness of the pattern formed on the substrate is within the allowable range of the set residual layer thickness.

According to the present embodiment, a drop recipe for the case where the space between the mold and the resin on the substrate is in an atmosphere of a condensable gas, such as pentafluoropropane, can be generated. In addition, according to the present embodiment, if the kind of resin or the concentration of pentafluoropropane is changed, a supply amount and supply positions of the resin included in the drop recipe can be optimized based on an obtained dissolution amount of pentafluoropropane into the resin. Consequently, the drop recipe for the case where the space between the mold and the resin on the substrate is in an atmosphere of a condensable gas, such as pentafluoropropane, can be generated in a short time.

### Second Embodiment

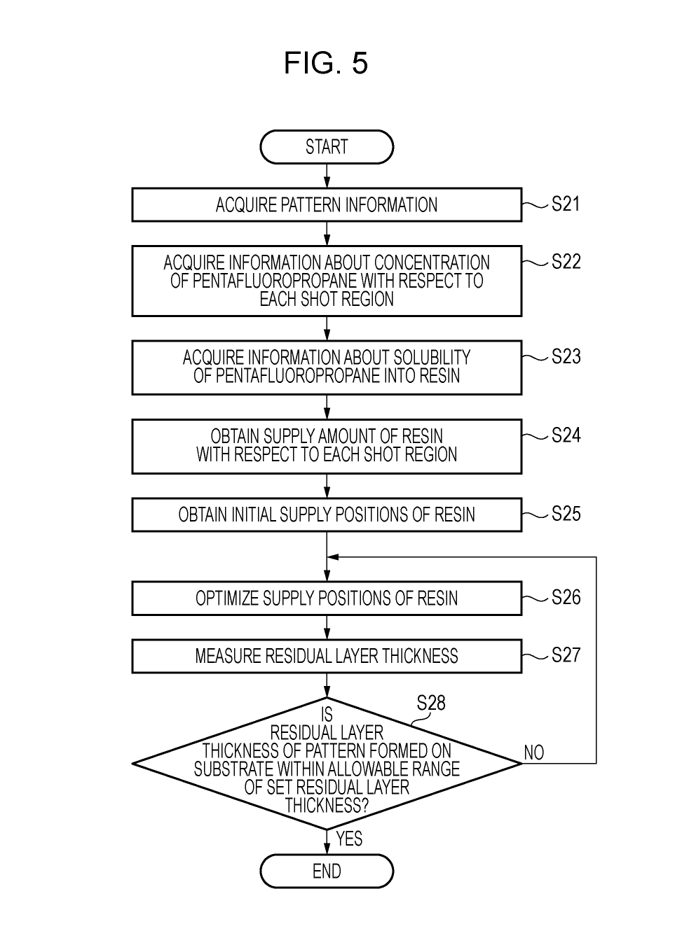

FIG. 5 is a flowchart of a method of generating a drop recipe for the case where the space between the mold 41 and the resin 30 on the substrate is in the pentafluoropropane atmosphere according to a second embodiment. The method of generating a drop recipe according to the present embodiment is fundamentally the same as that according to the first embodiment. Differences between the first and second embodiments will now be described.

The concentration of pentafluoropropane in the space between the mold 41 and the resin 30 on the substrate may vary depending on the position of a shot region of the substrate 21. For example, a condition of replacement by pentafluoropropane in central part of the substrate 21 differs from that in end part of the substrate 21 in the space between the mold 41 and the resin 30 on the substrate. The concentration of pentafluoropropane varies accordingly from one shot region to another of the substrate 21.

A movement distance of the substrate 21 from a position (supply position of the resin 30) under the dispenser 32 to a position (imprint position) under the mold 41 varies for each shot region of the substrate 21. If the movement distance of the substrate 21 is short, the duration of pentafluoropropane supply will be short. The concentration of pentafluoropropane in the space between the mold 41 and the resin 30 on the substrate may be reduced.

As illustrated in FIG. 5, in S22, information about the concentration of pentafluoropropane in the space between the mold 41 and the resin 30 on the substrate in imprint processing is acquired (obtained) with respect to each shot region of the substrate 21. For example, an optical interferometer, a flon detector, or an infrared spectrometer may be disposed in the imprint apparatus 10, and the concentration of pentafluoropropane with respect to each shot region can be measured in advance. In some embodiments, imprint processing is actually performed, the volume of a pattern formed on the substrate is measured, and the concentration of pentafluoropropane with respect to each shot region is estimated based on the volume shrinkage ratio of the pattern formed on the substrate to the resin 30 supplied to the substrate.

In S24, a supply amount of the resin 30 to be supplied to the substrate is obtained with respect to each shot region of the substrate 21 in the same manner as in S14 so that a set residual layer thickness is obtained in the case where pentafluoropropane is contained in the space between the mold 41 and the resin 30 on the substrate.

According to the present embodiment, a supply amount and supply positions of resin to be supplied to a substrate in the case where the space between the mold and the resin on the substrate is in an atmosphere of a condensable gas, such as pentafluoropropane, can be optimized with respect to each shot region of the substrate.

### Third Embodiment

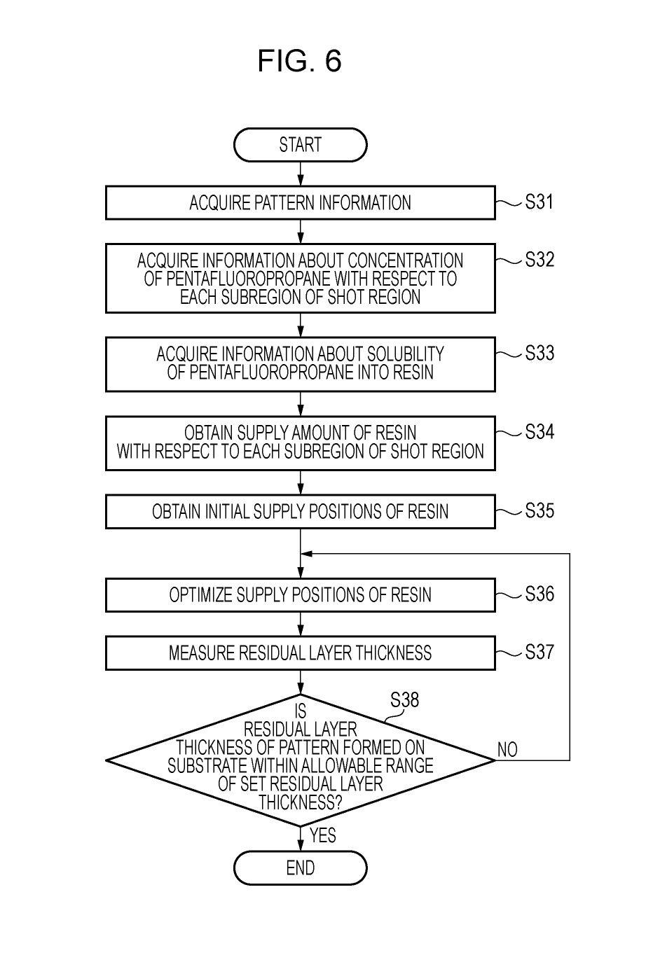

FIG. 6 is a flowchart of a method of generating a drop recipe for the case where the space between the mold 41 and the resin 30 on the substrate is in the pentafluoropropane atmosphere according to a third embodiment. The method of generating a drop recipe according to the present embodiment is fundamentally the same as that according to the first embodiment. Differences between the first and third embodiments will now be described.

The concentration of pentafluoropropane in the space between the mold 41 and the resin 30 on the substrate may vary from one position (subregion) to another (subregion) in each shot region of the substrate 21. For example, a condition of replacement by pentafluoropropane in central part of a shot region of the substrate 21 differs from that in peripheral part thereof in the space between the mold 41 and the resin 30 on the substrate, resulting in a variation in concentration of pentafluoropropane in the shot region.

If the pattern portion 41a of the mold 41 is deformed so as to protrude toward the substrate 21 and the pattern portion 41a is brought into contact with the resin 30 on the substrate such that central part of the pattern portion 41a first contacts the resin 30, there is a time lag between the time when the mold 41 contacts the resin 30 in central part of a shot region of the substrate 21 and the time when the mold 41 contacts the resin 30 in peripheral part thereof. This may cause the concentration of pentafluoropropane in the peripheral part of the shot region of the substrate 21 to be lower than that in the central part thereof.

As illustrated in FIG. 6, in S32, a shot region of the substrate 21 is divided into subregions, and information about the concentration of pentafluoropropane in the space between the mold 41 and the resin 30 on the substrate in imprint processing is acquired (obtained) with respect to each subregion. For example, imprint processing is actually performed, each shot region is divided into subregions of, for example, approximately 10 μm, and the volume of a pattern formed in each of the subregions is measured. Then, the concentration of pentafluoropropane with respect to each subregion is estimated based on the volume shrinkage ratio of the pattern formed in the subregion to the resin 30 supplied to the substrate.

In S34, a supply amount of the resin 30 to be supplied to the substrate is obtained with respect to each subregion of a shot region of the substrate 21 in the same manner as in S14 so that a set residual layer thickness is obtained in the case where pentafluoropropane is contained in the space between the mold 41 and the resin 30 on the substrate.

According to the present embodiment, a supply amount and supply positions of resin to be supplied to a substrate in the case where the space between the mold and the resin on the substrate is in an atmosphere of a condensable gas, such as pentafluoropropane, can be optimized with respect to each subregion of the shot region of the substrate.

### Fourth Embodiment

In each of the methods of generating a drop recipe according to the above-described embodiments, the area of a droplet of the resin 30 on the substrate at the time of contact between the mold 41 and the resin 30 on the substrate may be obtained, and a supply amount and supply positions of the resin 30 to be supplied to the substrate may be obtained based on the area.

A supply amount and supply positions of the resin 30 to be supplied from the dispenser 32 are controlled based on the drop recipe generated in each of the above-described embodiments. Since droplets of the resin 30 are discharged from the dispenser 32, an array of droplets of the resin 30 is formed in each shot region of the substrate 21.

In an atmosphere of a condensable gas, the condensable gas dissolves in the resin 30 on the substrate, resulting in a reduction in viscosity of the resin 30. The reduced-viscosity resin 30 fails to maintain its region (area) provided when supplied as a droplet to the substrate, so that the resin 30 gradually spreads, or the region gradually increases before the resin 30 is molded by the mold 41. If a droplet of the resin 30 contacts another, or adjacent droplet before the resin 30 is molded by the mold, a distribution of the resin 30 supplied to the substrate would vary, leading to a reduction in uniformity of a residual layer thickness of a pattern formed on the substrate.

According to the present embodiment, a supply amount and supply positions of the resin 30 to be supplied to the substrate are feedback-controlled based on information (third information) about the area of a droplet of the resin 30 on the substrate at the time of contact between the mold 41 and the resin 30 on the substrate. For example, a supply amount and supply positions of the resin 30 to be supplied to the substrate are optimized to prevent contact between adjacent droplets of the resin 30 until the mold 41 is brought into contact with the resin 30 on the substrate.

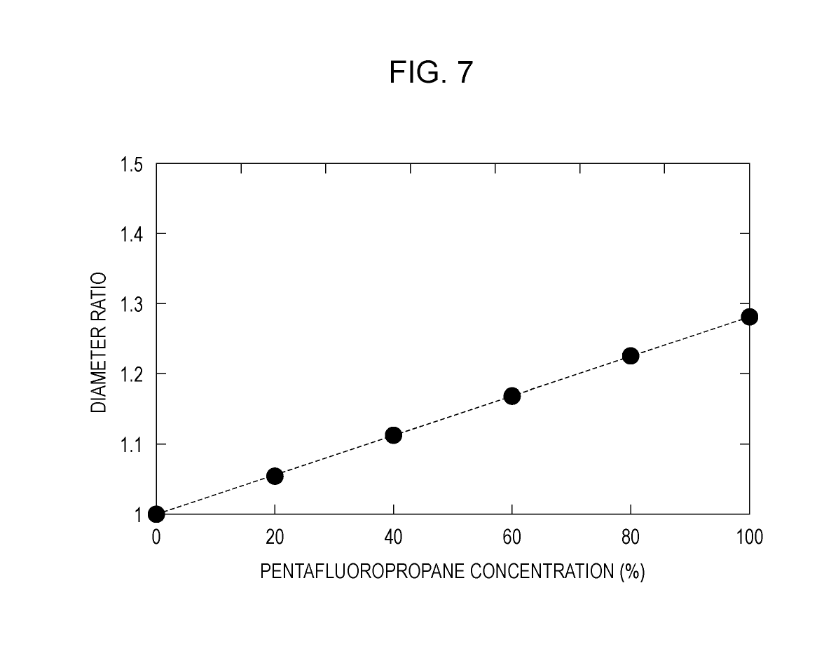

FIG. 7 is a graph illustrating the relationship between the concentration of the condensable gas and the diameter of a droplet of the resin 30 on the substrate. In this case, the condensable gas used was pentafluoropropane. In FIG. 7, the axis of ordinates denotes the ratio of the diameter of a droplet of the resin 30 on the substrate to the diameter of a droplet of the resin 30 at a pentafluoropropane concentration of 0%, and the axis of abscissas denotes the concentration [%] of pentafluoropropane.

Referring to FIG. 7, as the concentration of pentafluoropropane rises, the diameter of a droplet of the resin 30 on the substrate increases. As described above, contact between the condensable gas and the resin 30 results in a reduction in viscosity of the resin 30 (i.e., an increase in fluidity thereof). This facilitates spread of the resin 30. The area of a droplet of the resin 30 on the substrate at the time of contact between the mold 41 and the resin 30 on the substrate can be obtained based on the relationship of FIG. 7 and the concentration of pentafluoropropane obtained in the above-described manner in the embodiments. The viscosity of the resin 30 and solubility into the resin 30 depend on the kind of resin 30. It is necessary to obtain the relationship of FIG. 7 for each kind of resin 30.

The alignment scope 14 can be used to obtain the area of a droplet of the resin 30 on the substrate at the time of contact between the mold 41 and the resin 30 on the substrate. Specifically, a droplet of the resin 30 is discharged from the dispenser 32, and such a discharged state of the droplet is maintained for a period of time to be elapsed until molding with the mold 41 is performed in actual imprint processing. Then, the supplied resin 30 on the substrate is cured, the cured resin 30 is detected with the alignment scope 14, and the area of the resin 30 is obtained.

According to the present embodiment, a drop recipe can be generated that achieves a further increase in uniformity of the residual layer thickness of a pattern formed on a substrate in the case where the space between a mold and a resin on the substrate is in an atmosphere of a condensable gas, such as pentafluoropropane.

In the above description, the controller 15 acquires information about the concentration or solubility of a condensable gas from, for example, an external device. In some embodiments, the imprint apparatus 10 includes a measurement device that measures the concentration and solubility of a condensable gas.

The imprint apparatus 10 generates a drop recipe using the generating method according to any of the above-described embodiments, and supplies the resin 30 to a substrate with the dispenser 32 based on the drop recipe.

Then, the apparatus supplies a condensable gas to the space between the mold 41 and the resin 30 on the substrate and performs imprint processing while the space is supplied with the condensable gas. The imprint apparatus 10 can form a pattern on the substrate such that the pattern has a residual layer thickness within an allowable range and has uniformity in the case where the space between the mold and the resin on the substrate is in an atmosphere of a condensable gas, such as pentafluoropropane.

A method of manufacturing an article, such as a device (e.g., a semiconductor device, a magnetic storage medium, or a liquid crystal display device), according to an embodiment of the present disclosure will now be described. The method includes forming a pattern on a substrate (e.g., a wafer, a glass plate, or a film substrate) using the imprint apparatus 10. The method further includes processing the substrate with the formed pattern. The processing may involve removing a residual layer of the pattern. The processing may involve another known step, such as etching the substrate using the pattern as a mask. The method of manufacturing an article according to the present embodiment is advantageous in at least one of performance, quality, productivity, and production cost of the article over related-art methods.

The present disclosure can be achieved by supplying a program for implementing one or more functions of the above-described embodiments to a system or an apparatus through a network or a storage medium, and allowing one or more processors in a computer of the system or the apparatus to read out and execute the supplied program. The present disclosure can also be achieved by a circuit (for example, an application-specific integrated circuit, or ASIC) that implements one or more functions.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2015-223338, filed Nov. 13, 2015, which is hereby incorporated by reference herein in its entirety.

What is claimed is:

1. A method of generating a recipe for supplying an imprint material onto a substrate, the imprint material being used in imprint processing of forming a pattern on the substrate with the imprint material and a mold, the method comprising steps of:
obtaining first information about a volume of a pattern of the mold;
obtaining second information about a concentration of a condensable gas to be supplied to a space between the mold and the imprint material on the substrate, the condensable gas having a property of being liquefied by contact between the mold and the imprint material; and
generating the recipe based on the first information and the second information.

2. The method according to claim 1, further comprising a step of:
obtaining third information about an area of a droplet of the imprint material at a time of contact between the mold and the imprint material on the substrate,
wherein the generating step generates the recipe further based on the third information.

3. The method according to claim 2, further comprising a step of:
obtaining fourth information about arrangement of elements of a pattern of the mold,
wherein the recipe includes information about a supply position of a droplet of the imprint material on the substrate, and
wherein the generating step generates the recipe further based on the fourth information.

4. The method according to claim 1, further comprising a step of:
obtaining fifth information about a solubility of the condensable gas into the imprint material,
wherein the generating step generates the recipe further based on the fifth information.

5. The method according to claim 4, further comprising a step of:
obtaining a supply amount of the imprint material to be supplied to the substrate based on the fifth information.

6. The method according to claim 5, wherein the step of obtaining the supply amount obtains a dissolution amount of the condensable gas into the imprint material based on the first information, the second information and the fifth information, and obtains the supply amount based on the dissolution amount.

7. The method according to claim 1,
wherein the generating step generates the recipe with respect to each of shot regions of the substrate.

8. The method according to claim 1,
wherein the step of obtaining the second information obtains the second information with respect to each of subregions of a shot region of the substrate, and
wherein the generating step generates the recipe based on the second information with respect to each of the subregions.

9. The method according to claim 1, wherein the condensable gas has a solubility not less than 0.2 mol/L into the imprint material at 20° C. and 1 atm.

10. The method according to claim 1, wherein the condensable gas includes pentafluoropropane.

11. A method of preforming imprint processing of forming a pattern on a substrate with an imprint material and a mold, the method comprising a step of:
generating a recipe for supplying the imprint material onto the substrate using the method according to claim 1.

12. An imprint apparatus that performs imprint processing of forming a pattern on a substrate with an imprint material and a mold, the apparatus comprising:
a supply device configured to supply the imprint material onto the substrate based on a recipe generated by a generating method and used to supply the imprint material onto the substrate,
wherein the generating method generates the recipe and includes steps of:
obtaining first information about a volume of a pattern of the mold;
obtaining second information about a concentration of a condensable gas to be supplied to a space between the mold and the imprint material on the substrate, the condensable gas having a property of being liquefied by contact between the mold and the imprint material; and
generating the recipe based on the first information and the second information.

13. A computer readable storage medium storing a program that causes a computer to execute a generating method,
wherein the generating method generates a recipe for supplying an imprint material onto a substrate, the imprint material being used in imprint processing of forming a pattern on the substrate with the imprint material and a mold, and includes steps of:
obtaining first information about a volume of a pattern of the mold;
obtaining second information about a concentration of a condensable gas to be supplied to a space between the mold and the imprint material on the substrate, the condensable gas having a property of being liquefied by contact between the mold and the imprint material; and
generating the recipe based on the first information and the second information.

14. A method of manufacturing an article, the method comprising steps of:
forming a pattern on a substrate using an imprint apparatus; and
processing the substrate, on which the pattern has been formed, to manufacture the article,
wherein the imprint apparatus performs imprint processing of forming the pattern on the substrate with an imprint material and a mold, and includes:
a supply device configured to supply the imprint material onto the substrate based on a recipe generated by a generating method and used to supply the imprint material onto the substrate, and
wherein the generating method generates the recipe and includes steps of:
obtaining first information about a volume of a pattern of the mold;
obtaining second information about a concentration of a condensable gas to be supplied to a space between the mold and the imprint material on the substrate, the condensable gas having a property of being liquefied by contact between the mold and the imprint material; and
generating the recipe based on the first information and the second information.
